(19) United States
(12) Patent Application Publication
(10) Pub. No.: US 2014/0369524 A1
(43) Pub. Date: Dec. 18, 2014

(54) WAVE ADJUSTMENT TOOL (WAT)

(71) Applicant: Lloyd Trammell, Thousand Oaks, CA (US)

(72) Inventor: Lloyd Trammell, Thousand Oaks, CA (US)

(73) Assignee: Max Sound Corporation, La Jolla, CA (US)

(21) Appl. No.: 14/183,292

(22) Filed: Feb. 18, 2014

Related U.S. Application Data
(60) Provisional application No. 61/766,077, filed on Feb. 18, 2013.

(51) Int. Cl. H03G 5/16

(52) U.S. Cl. CPC H03G 5/165
USPC 381/103

(57) ABSTRACT

A Wave Adjustment Tool process and system for customizing sound is provided. An input audio sound is received. A tone adjusting circuit that comprises three sections, including a first section for adjusting a low frequency tone; a second section for adjusting a mid frequency tone; and a third section for adjusting a high frequency tone. Audio processed by the first, second and third sections are mixed to produce an output audio sound. According to an exemplary embodiment the low frequency tone has a frequency of 100 Hz and a bandwidth of 0.5.; the mid frequency tone has a frequency of 2500 Hz and an adjustable bandwidth; and the high frequency tone has a frequency of 10 KHz and an adjustable bandwidth.

### CROSS-REFERENCE TO RELATED PATENT APPLICATIONS

Embodiments of the present invention relate to U.S. Provisional Application Ser. No. 61/766,077, filed Feb. 18, 2013, entitled “WAVE ADJUSTMENT TOOL (WAT)”, the contents of which are incorporated by reference herein and which is a basis for a claim of priority.

### BACKGROUND OF THE INVENTION

In sound recording and reproduction, equalization is the process commonly used to alter the frequency response of an audio system using linear filters. Most hi-fi equipment uses relatively simple filters to make bass and treble adjustments. Graphic and parametric equalizers have much more flexibility in tailoring the frequency content of an audio signal. An equalizer is the circuit or equipment used to achieve equalization. Since equalizers, adjust the amplitude of audio signals at particular frequencies, they are, in other words, frequency-specific volume knobs.¹ ¹ http://en.wikipedia.org/wiki/Equalization_(audio)

Equalizers are used in recording studios, broadcast studios, and live sound reinforcement to correct the response of microphones, instrument pick-ups, loudspeakers, and hall acoustics. Equalization may also be used to eliminate unwanted sounds, make certain instruments or voices more prominent, enhance particular aspects of an instrument's tone, or combat feedback (howling) in a public address system. Equalizers are also used in music production to adjust the timbre of individual instruments by adjusting their frequency content and to fit individual instruments within the overall frequency spectrum of the mix. ² ² See, n.1, above

The most common equalizers in music production are parametric, semi-parametric, graphic, peak, and program equalizers. Graphic equalizers are often included in consumer audio equipment and software which plays music on home computers. Parametric equalizers require more expertise than graphic equalizers, and they can provide more specific compensation or alteration around a chosen frequency. This may be used in order to remove (or to create) a resonance, for instance. ³ ³ See, n.1, above

Tone control is a type of equalization used to make specific pitches or “frequencies” in an audio signal softer or louder. A tone control circuit is an electronic circuit that consists of a network of filters which modify the signal before it is fed to speakers, headphones or recording devices by way of an amplifier.

Conventional tone control method is thus a static setting that can increase or decrease a fixed amount at a single frequency and bandwidth. While this does allow the user to customize a sound to his preference, as soon as anything changes this setting may not be desirable and the user will either accept compromise or be continually changing the amounts as different content is played.⁴ ⁴ http://en.wikipedia.org/wiki/Tone_control_circuit

There is a need for an application that addresses the above deficiencies of existing systems that can add clarity to received audio.

### SUMMARY OF THE INVENTION

A Wave Adjustment Tool (WAT) process and system for customizing sound is provided. According to an exemplary embodiment, an input audio sound is received and is treated by a tone adjusting circuit that comprises three sections, including a first section for adjusting a low frequency tone; a second section for adjusting a mid frequency tone; and a third section for adjusting a high frequency tone. Audio processed by the first, second and third sections are mixed to produce an output audio sound.

According to an exemplary embodiment of the present invention the low frequency tone has a frequency of 100 Hz and a bandwidth of 0.5.; the mid frequency tone has a frequency of 2500 Hz and an adjustable bandwidth; and the high frequency tone has a frequency of 10 KHz and an adjustable bandwidth.

The inventive Wave Adjustment Tool is a different approach in that it dynamically monitors the audio content and adjusts itself to compensate for these changes in both a positive and negative direction. The end result is very pleasing and a more natural sound of the content being played.

The WAT process is not limited only three bands. More dynamic bands may be added as desired by programming them into the process and assigning the frequency, band width, and amount of dynamic change to be allowed per band. In this case it is a digital process, but it may be hardware (analog) if desired in any output format (mono, stereo, 5.1, 7,1, etc.)

### BRIEF DESCRIPTION OF THE DRAWINGS

FIG. 1 is a block diagram of an exemplary embodiment of the Wave Adjustment Tool according to the present invention.

FIG. 2 shows a typical use/implementation of the inventive Wave Adjustment Tool according to the present invention.

### DETAILED DESCRIPTION OF THE PREFERRED EMBODIMENT(S)

The Wave Adjustment Tool of the present invention is an improvement over the conventional tone adjustments in part because it is based on a dynamic approach that monitors the content of the received audio and adjusts itself to compensate for any changes in both a positive and negative direction. The end result is very pleasing and a more natural sound of the content being played. The WAT© is not limited only three bands. More dynamic bands may be added as desired by programming them into the process and assigning the frequency, band width, and amount of dynamic change to be allowed per band. In this case it is a digital process, but it may be hardware (analog) if desired in any output format (mono, stereo, 5.1, 7,1, etc.)

WAT is a three section tone adjusting circuit with some dynamic control. The sections are LOW (bass), MID, and HIGH (treble).

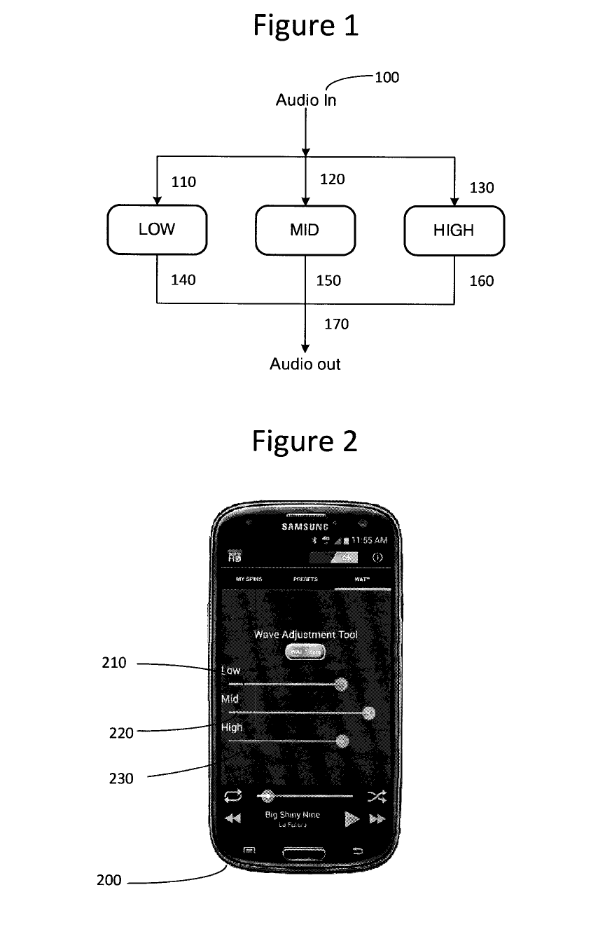

Per FIG. 1, input audio 100 is received for processing by the Wave Adjustment Tool of the present invention. Input audio 100 is processed in parallel by the three sections of the WAT tone adjusting circuit, which include the LOW 110, MID 120 and HIGH 130 sections. The audio processed by the three sections (shown by reference numerals 140, 150 and 160 in FIG. 2) are then mixed to form output audio 170.

According to one embodiment of the present invention the LOW section has a frequency of 100 Hz and a 0.5 bandwidth; MID has a frequency of 2500 Hz with an adjustable bandwidth; and HIGH has a 10 kHz frequency and a 0.5 bandwidth.

For MID, the center frequency is dynamically moved in both positive and negative amounts according to the input level of this bandpass filter. Preferably, the range is from 1.7 kHz on the low end to 4.5 kHz on the upper end with 2.5 kHz as the center or nominal setting. As the input level goes positive or negative, so the bandwidth will change. For a negative change the bandwidth will increase, for e.g., to a 0.5, while a positive change will decrease, for e.g., to a 0.1. This provides a larger frequency change for negative and a smaller, more precise change for positive level amounts in the filtered audio content.

In reference to the HIGH tone control section the center frequency is fixed, e.g., at 10 kHz, but the bandwidth changes dynamically in positive amounts as the input level changes. For negative amounts the bandwidth stays at, e.g., 0.5, when the level decreases the bandwidth goes only to a max bandwidth of e.g., 0.3.

FIG. 3 shows a typical use/implementation of the inventive WAT process for smartphone 200 and its graphic configuration or look. In this example, there is a plus and minus amount with the center of the line being “zero”, or no effect. When user moves one of the controls, the “WAT Zero” box appears indicating that a change has been made from the zero position. Pressing the WAT Zero button will return all of the faders to a zero position and the button will disappear until a change is made. The Low, Mid and High adjustment bars are respectively identified by reference numerals 210, 220 and 230.

What is claimed is:

1. A Wave Adjustment Tool process and system for customizing sound comprising:
Receiving an input audio sound;
A tone adjusting circuit, comprising three sections comprising;
A first section for adjusting a low frequency tone;
A second section for adjusting a mid frequency tone;
A third section for adjusting a high frequency tone;
Mixing the audio outputs processed by the first, second and third sections to produce an output audio sound.

2. The Wave Adjustment Tool process of claim 1, wherein the low frequency tone has a frequency of 100 Hz and a bandwidth of 0.5.

3. The Wave Adjustment Tool process of claim 1, wherein the mid frequency tone has a frequency of 2500 Hz and an adjustable bandwidth.

4. The Wave Adjustment Tool process of claim 1, wherein the high frequency tone has a frequency of 10 KHz and an adjustable bandwidth.
